(19) United States
(12) Patent Application Publication
(10) Pub. No.: US 2003/0016766 A1
(43) Pub. Date: Jan. 23, 2003

(54) Phase difference detecting circuit

(76) Inventor: Yoshiaki Ito, Tokyo (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 10/141,116

(22) Filed: May 9, 2002

(30) Foreign Application Priority Data
Jul. 23, 2001 (JP) 2001-222098

(51) Int. Cl. H03D 3/24

(52) U.S. Cl. 375/326

(57) ABSTRACT

A phase difference detecting circuit comprises a flip-flop circuit 2 for comparing the phase of an input signal A with that of an input signal B and outputting the compared result, flip-flop circuits 3P1 to 3Pn for comparing the phases of the input signals A delayed respectively by delay circuits 1P1 to 1Pn with that of the input signal B and outputting the compared results, and flip-flop circuits 3N1 to 3Nn for comparing the phase of the input signal A with that of the input signals B delayed respectively by delay circuits 1N1 to 1Nn and outputting the compared results.

### BACKGROUND OF THE INVENTION

1. Field of the Invention

The present invention relates to a phase difference detecting circuit for detecting the phase difference between two input signals.

2. Description of the Related Art

With the development of the fine patterning of an LSI, a power voltage is being lowered to improve the reliability of a transistor and to reduce the power consumption thereof. Lowering the power voltage means reducing a design margin of an analog circuit and may have the possibility that designing of the analog circuit itself would become impossible. To this end, what is thought of is to digitalize a circuit which has been conventionally designed as an analog circuit.

Also a phase locked loop (hereinafter referred to as PLL) and a delay locked loop (hereinafter referred to as DLL) are driven by necessity of digitalization with this trend.

FIG. 7 is a block diagram showing a conventional phase difference detector circuit in a PLL circuit. FIG. 8 is a timing chart showing the operation of a conventional phase difference detecting circuit.

Next, the operation of a phase difference detecting circuit will be described.

For example, as shown in FIG. 8, in the case where the phase of an input signal A leads that of an input signal B, a conventional phase difference detecting circuit outputs an output signal A of a pulse width corresponding to a phase difference between the input signal A and the input signal B.

Such a constitution of the conventional phase difference detecting circuit as shown in the above forces the detected result of the phase difference to be expressed in analog (the pulse width of the output signal A expresses the phase difference). For this reason, this makes it difficult to digitalize the subsequent stage of the phase difference detecting circuit and precludes the digitalization of a PLL circuit and a DLL circuit.

### SUMMARY OF THE INVENTION

The present invention has been made to solve the above problem. An object of the present invention is to provide a phase difference detecting circuit which enables expression of the detected result of a phase difference in digital.

A phase difference detecting circuit according to the present invention comprises first phase comparing means for comparing the phase of the first input signal with that of the second input signal and outputting the compared result; second phase comparing means for comparing the phase of the second input signal with that of the first input signal delayed by the first delay circuit and outputting the compared result; and third phase comparing means for comparing the phase of the first input signal with that of the second input signal delayed by the second delay circuit and outputting the compared result.

In the phase difference detecting circuit according to the present invention, each of the first, second, and third phase comparing means comprises a flip-flop circuit in which, in the case where the phase of the first input signal leads that of the second input signal, a signal of a level H is outputted from an output terminal corresponding to the first input signal and a signal of a level L is outputted from an output terminal corresponding to the second input signal, whereas in the case where the phase of the first input signal lags that of the second input signal, a signal of a level L is outputted from an output terminal corresponding to the first input signal and a signal of a level H is outputted from an output terminal corresponding to the second input signal.

A phase difference detecting circuit according to the present invention comprises first phase comparing means for comparing the phase of the first input signal with that of the second input signal and outputting the compared result; a plurality of second phase comparing means for comparing the phase of the second input signal with that of the first input signals delayed respectively by a plurality of first delay circuits and outputting the compared results ; and a plurality of third phase comparing means for comparing the phase of the first input signal with that of the second input signals delayed respectively by a plurality of second delay circuits and outputting the compared results.

In the phase difference detecting circuit according to the present invention, each of the first comparing means, a plurality of second phase comparing means and a plurality of third phase comparing means comprises a flip-flop circuit in which, in the case where the phase of the first input signal leads that of the second input signal, a signal of a level H is outputted from an output terminal corresponding to the first input signal and a signal of a level L is outputted from an output terminal corresponding to the second input signal, whereas in the case where the phase of the first input signal lags that of the second input signal, a signal of a level L is outputted from an output terminal corresponding to the first input signal and a signal of a level H is outputted from an output terminal corresponding to the second input signal.

In the phase difference detecting circuit according to the present invention, each of a plurality of first delay circuits comprises a different number of delay elements connected in series and each of a plurality of second delay circuits comprises those connected in series.

In the phase difference detecting circuit according to the present invention, the number of delay elements mounted in each of a plurality of first delay circuits and those mounted in each of a plurality of second delay circuits increase at an exponential rate.

In the phase difference detecting circuit according to the present invention, the number of delay elements mounted in each of a plurality of first delay circuits and those mounted in each of a plurality of second delay circuits increase in an arithmetic progression.

The phase difference detecting circuit according to the present invention is applied to the phase difference detecting circuit section of a PLL circuit.

The phase difference detecting circuit according to the present invention is applied to the phase difference detecting circuit section of a DLL circuit.

The above and other objects and the attendant advantages of the invention will become readily apparent by referring to the following detailed description when considered in conjunction with the accompanying drawings, wherein:

### BRIEF DESCRIPTION OF THE DRAWINGS

FIG. 1 is a block diagram showing a phase difference detecting circuit according to a first embodiment of the present invention.

FIG. 2 is a timing chart showing the operation of the phase difference detecting circuit in FIG. 1.

FIG. 3 is a block diagram showing a phase difference detecting circuit according to a second embodiment of the present invention.

FIG. 4 is a timing chart showing the operation of the phase difference detecting circuit in FIG. 1.

FIG. 5 is a block diagram showing a PLL circuit.

FIG. 6 is a block diagram showing a DLL circuit.

FIG. 7 is a block diagram showing a conventional phase difference detecting circuit in a PLL circuit.

FIG. 8 is a timing chart showing the operation of a conventional phase difference detecting circuit.

Throughout the figures, the same reference numerals, and characters, unless otherwise noted, are used to denote like features, elements, components, or portions of the illustrated embodiment.

### DESCRIPTION OF THE PREFERRED EMBODIMENTS

The preferred embodiments of the present invention will be described in details with reference to the attached drawings.

### First Embodiment

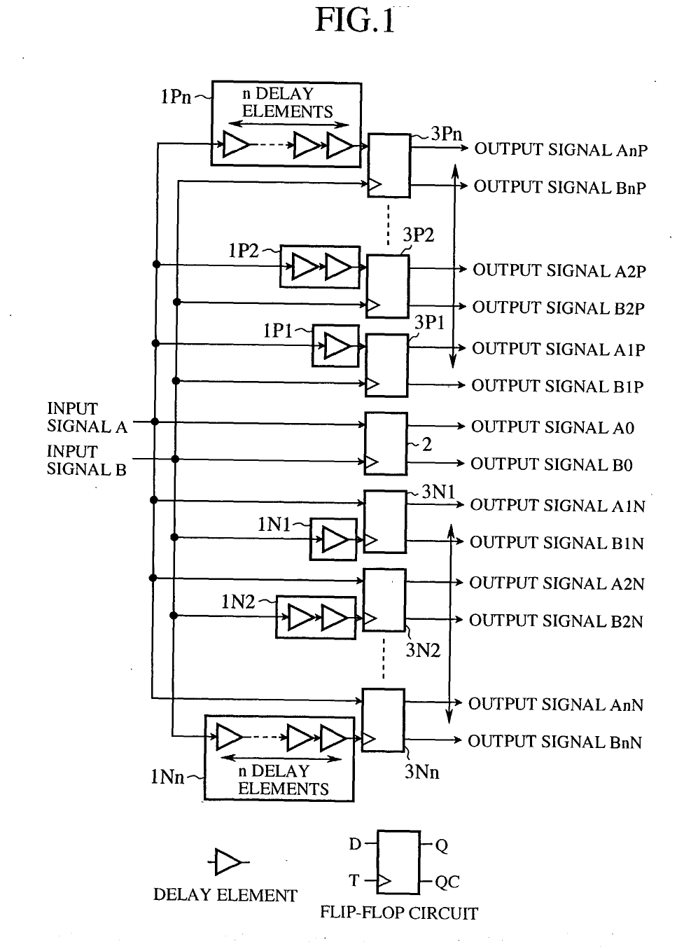

FIG. 1 is a block diagram showing a phase difference detecting circuit according to a first embodiment of the present invention. Referring now to FIG. 1, reference characters 1P1 to 1Pn denote delay circuits (first delay circuits) for delaying an input signal A (first input signal) by different period of times from each other in which a delay circuit 1P1 is formed of one delay element, a delay circuit 1P2 of two delay elements, and a delay circuit 1Pn of n delay elements. Reference characters 1N1 to 1Nn denote delay circuits (second delay circuits) for delaying an input signal B (second input signal) by different period of times from each other in which a delay circuit 1N1 is formed of one delay element, a delay circuit 1N2 of two delay elements, and a delay circuit 1Nn of n delay elements.

A reference character 2 denotes a flip-flop circuit (first phase comparing means) for comparing the phase of the input signal A with that of the input signal B and outputting the compared results. Reference characters 3P1 to 3Pn denote flip-flop circuits (second phase comparing means) for comparing the phases of the input signals A, delayed by the delay circuits 1P1 to 1Pn, with that of the input signal B and outputting the compared results. Reference characters 3N1 to 3Nn designate flip-flop circuits (third phase comparing means) for comparing the phase of the input signal A with that of the input signals B, delayed by the delay circuits 1N1 to 1Nn, and outputting the compared results.

Here, in the case where the phase of the input signal A leads that of the input signal B, each of the flip-flop circuits 2, 3P1 to 3Pn, and 3N1 to 3Nn outputs a signal of a level H from an output terminal Q corresponding to the input signal A and outputs a signal of a level L from an output terminal QC corresponding to the input signal B. On the other hand, in the case where the phase of the input signal Alags that of the input signal B, each of the flip-flop circuits 2, 3P1 to 3Pn, and 3N1 to 3Nn outputs a signal of a level L from the output terminal Q and outputs a signal of a level H from the output terminal QC. However, in the case where the input signal A and the input signal B are inputted at the same time a signal of a level H is outputted from the output terminal Q and a signal of level L is outputted from the output terminal QC.

Next, the operation of the phase difference detecting circuit will be described.

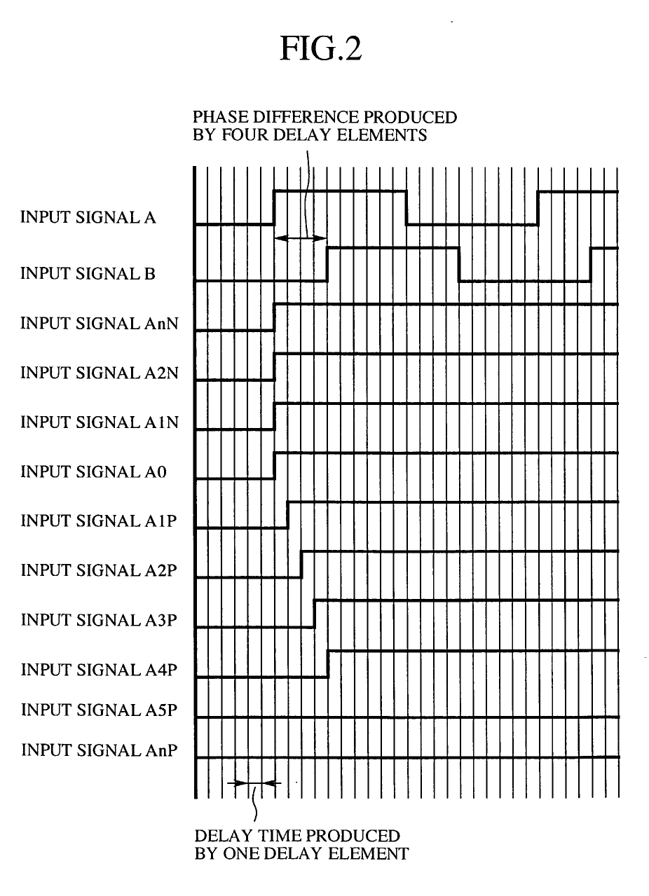

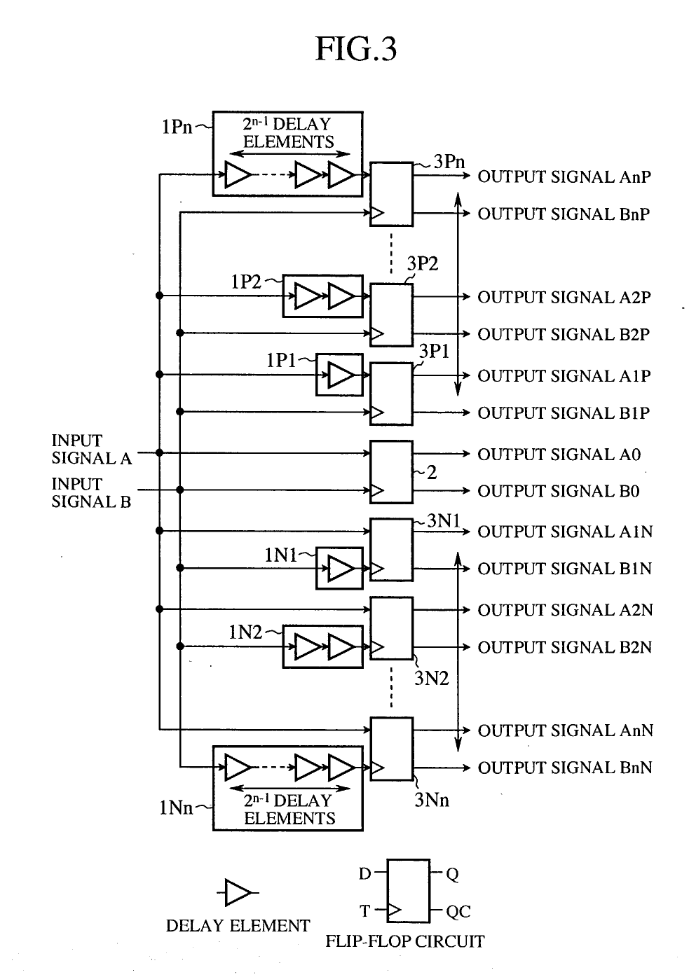

FIG. 2 is a timing chart showing the operation of the phase difference detecting circuit in FIG. 1.

For example, in the case where the phase of the input signal A leads that of the input signal B by four delay elements, as shown in FIG. 2, the phase difference detecting circuit outputs the signals of a level H from the respective output terminals Q of the flip-flop circuits 2, 3N1 to 3Nn at the time the input signal A is inputted because the respective delay circuits 1N1 to 1Nn further delay the input of the input signal B.

The phase difference detecting circuit continues to output the signals of a level H from the respective output terminals Q of the flip-flop circuits 3P1 to 3P4 until the input signal B is inputted because the respective delay circuits 1P1 to 1P4 delay the input of the input signal A but the input signal A is inputted before the input signal B is done.

Further, the phase difference detecting circuit outputs the signals of a level L from the respective output terminals Q of the flip-flop circuits 3P5 to 3Pn because the respective delay circuits 1P5 to 1Pn delay the input of the input signal A and thus the input signal B is input before the input signal A is done.

Therefore, paying an attention to the signal levels outputted from the respective output terminals Q of the flip-flop circuits 3Nn to 3Nl, 2, 3P1 to 3Pn, the signal levels are “H . . . H H H H L L . . . L”, so the subsequent stage of the phase difference detecting circuit can detect the phase difference between the input signal A and the input signal B if it detects where the boundary between the signal levels “H” and “L” is. In the example in FIG. 2, since the boundary is placed between the output signal A4P of the flip-flop circuit 3P4 and the output signal A5P of the flip-flop circuit 3P5, it can be found that the phase difference between the input signal A and the input signal B is produced by four delay elements.

As is clear from the above discussion, according to the present embodiment 1, since the phase difference detecting circuit comprises the flip-flop circuit 2 which compares the phase of the input signal A with that of the input signal B and outputs the compared result, the flip-flop circuits 3P1 to 3Pn for comparing the phases of the input signals A delayed respectively by the delay circuits 1P1 to 1Pn with that of the input signal B and outputs the compared results, and the flip-flop circuits 3Nl to 3Nn for comparing the phase of the input signal A with that of the input signals B delayed respectively by the delay circuits 1P1 to 1Pn and outputs the compared results, it allows expression of the detected result of the phase difference in digital.

### Second Embodiment

FIG. 3 is a block diagram showing a phase difference detecting circuit according to a second embodiment of the present invention.

While the number of delay elements mounted in each of the delay circuits 1P1 to 1Pn, 1N1 to 1Nn are increased one by one, in the manner of “1, 2, 3, 4, 5, . . . n” in the above first embodiment, the number of delay elements mounted in each of the delay circuits 1P1 to 1Pn, 1N1 to 1Nn may be increased at an exponential rate.

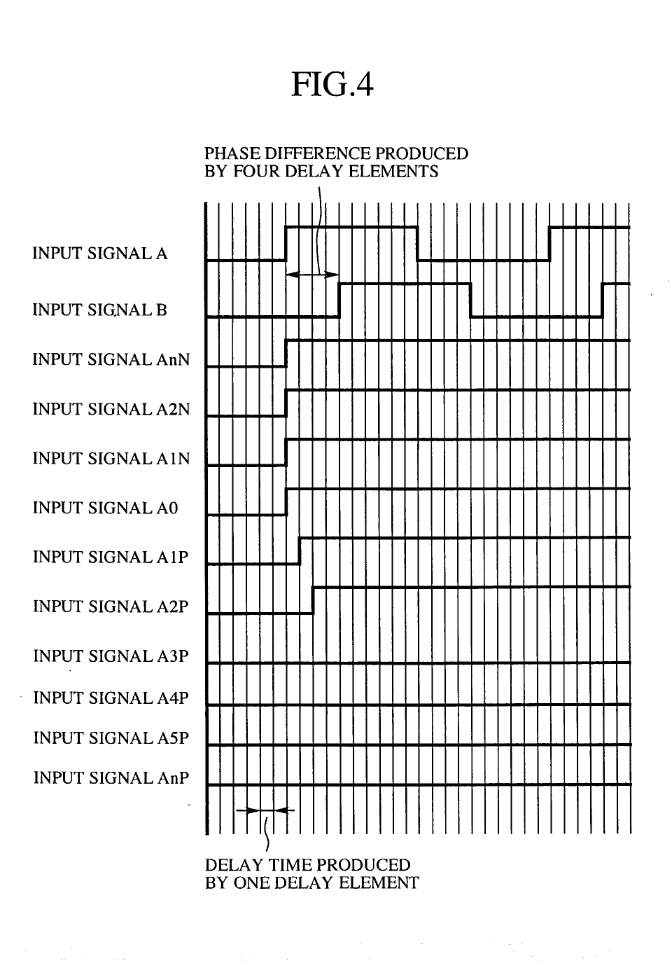

For example, as shown in FIG. 3, the number of delay elements mounted in each of the delay circuits 1P1 to 1Pn, 1N1 to 1Nn may be increased by a factor of two in the manner of “1, 2, 4, 8, 16, . . . 2ⁿ⁻¹”. FIG. 4 is a timing chart showing the operation of the phase difference detecting circuit in FIG. 3. This allows expansion of the detection range of the phase difference without increasing the number of flip-flop circuits.

In this connection, needless to say, the number of delay elements may be increased not only by a factor of two but also, for example, by a factor of three or four.

### Third Embodiment

While the number of delay elements mounted in each of the delay circuits 1P1 to 1Pn, 1N1 to 1Nn are increased one by one, in the manner of “1, 2, 3, 4, 5, . . . n” in the above first embodiment, the number of delay elements mounted in each of the delay circuits 1P1 to 1Pn, 1N1 to 1Nn may be increased in an arithmetic progression.

For example, the number of the delay elements mounted in the delay circuits 1P1 to 1Pn, 1N1 to 1Nn may be increased by two, in the manner of “1, 3, 5, 7, 9, . . . , 2n−1”. This permits expansion of the detection range of the phase difference without increasing the number of flip-flop circuits.

### Forth Embodiment

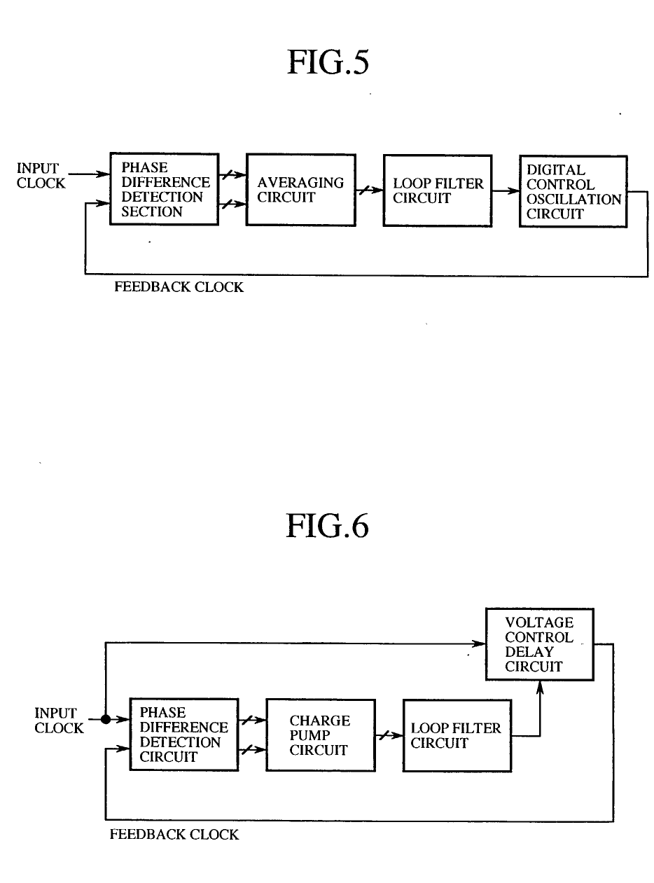

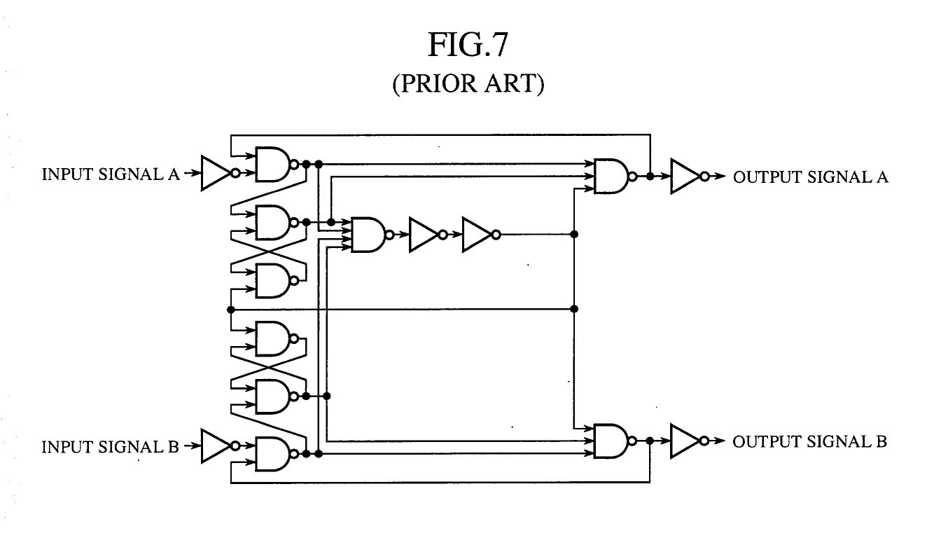

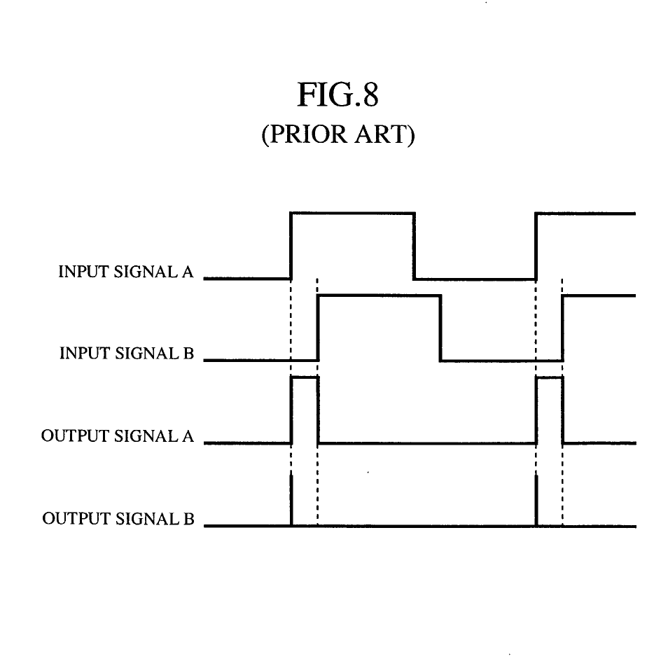

FIG. 5 is a block diagram showing a PLL circuit.

While no reference has been particularly made in the above first to third embodiments, the phase difference detecting circuits in the above first to third embodiments may be applied to the phase difference detection section of a PLL circuit shown in FIG. 5. This allows digitalization of the PLL circuit.

### Fifth Embodiment

FIG. 6 is a block diagram showing a DLL circuit.

While no reference has been particularly made in the above first to third embodiments, the phase difference detecting circuits in the above first to third embodiments may be applied to the phase difference detection section of a DLL circuit shown in FIG. 6. This permits digitalization of the DLL circuit.

### EFFECTS OF THE INVENTION

As described above, since a phase difference detecting circuit according to the present invention comprises first phase comparing means for comparing the phase of the first input signal with that of the second input signal and outputting the compared result; second phase comparing means for comparing the phase of the second input signal with that of the first input signal delayed by the first delay circuit and outputting the compared result; and third phase comparing means for comparing the phase of the first input signal with that of the second input signal delayed by the second delay circuit and outputting the compared result, it enables expression of the detected result of the phase difference in digital.

In a phase difference detecting circuit according to the present invention, each of the first, second and third phase comparing means comprises a flip-flop circuit in which, in the case where the phase of the first input signal leads that of the second input signal, a signal of a level H is outputted from an output terminal corresponding to the first input signal and a signal of a level L is outputted from an output terminal corresponding to the second input signal, whereas in the case where the phase of the first input signal lags that of the second input signal, a signal of a level L is outputted from an output terminal corresponding to the first input signal and a signal of a level H is outputted from an output terminal corresponding to the second input signal. Therefore, this enables output of the compared result of the phase without complicating the configuration of the circuit.

Since a phase difference detecting circuit according to the present invention comprises first phase comparing means for comparing the phase of the first input signal with that of the second input signal and outputting the compared result; a plurality of second phase comparing means for comparing the phase of the second input signal with that of the first input signals delayed respectively by a plurality of first delay circuits and outputting the compared results; and a plurality of third phase comparing means for comparing the phase of the first input signal with that of the second input signals delayed respectively by a plurality of second delay circuits and outputting the compared results, it allows expression of the detected result of the phase difference in digital.

In a phase difference detecting circuit according to the present invention, each of the first comparing means, a plurality of second phase comparing means and a plurality of third phase comparing means comprises a flip-flop circuit in which, in the case where the phase of the first input signal leads that of the second input signal, a signal of a level H is outputted from an output terminal corresponding to the first input signal and a signal of a level L is outputted from an output terminal corresponding to the second input signal, whereas in the case where the phase of the first input signal lags that of the second input signal, a signal of a level L is outputted from an output terminal corresponding to the first input signal and a signal of a level H is outputted from an output terminal corresponding to the second input signal. Therefore, this allows output of the compared result of the phase without complicating the configuration of the circuit.

In a phase difference detecting circuit according to the present invention, each of a plurality of first delay circuits comprises a different number of delay elements connected in series, and each of a plurality of second delay circuits comprises those connected in series. Therefore, the phase difference detecting circuit allows easy delay of the input signal.

In a phase difference detecting circuit according to the present invention, the number of delay elements mounted in each of a plurality of first delay circuits and those mounted in each of a plurality of second delay circuits increase at an exponential rate. Therefore, the phase difference detecting circuit permits expansion of the detection range of the phase difference.

In a phase difference detecting circuit according to the present invention, the number of delay elements mounted in each of a plurality of first delay circuits and those mounted in each of a plurality of second delay circuits increase in an arithmetic progression. Therefore, the phase difference detecting circuit permits expansion of the detection range of the phase difference.

Since a phase difference detecting circuit according to the present invention is constituted so that it is applied to the phase difference detecting circuit section of a PLL circuit, it permits digitalization of the PLL circuit.

Since the phase difference detecting circuit according to the present invention is constituted so that it is applied to the phase difference detecting circuit section of a PLL circuit, it permits digitalization of the PLL circuit.

While, in the preferred embodiments of the invention, digitalization of the phase difference detecting circuit is given as an example, it should be understood by those skilled in the art that various modifications and changes may be made without departing from the spirit and scope of the invention.

Also, it should be noted that the invention meets all the objects mentioned above and also has the advantages of wide commercial utility, and that the invention has been set forth for purposes of illustration only and not of limitation. That is, the invention is limited only by the following claims which follow. Consequently, reference should be made to the following claims in determining the full scope of the invention.

What is claimed is:

1. A phase difference detecting circuit comprising:
first phase comparing means for comparing the phase of a first input signal with that of a second input signal and outputting the compared result;
a first delay circuit for delaying the first input signal;
a second delay circuit for delaying the second input signal;
second phase comparing means for comparing the phase of the second input signal with that of the first input signal delayed by the first delay circuit and outputting the compared result; and
third phase comparing means for comparing the phase of the first input signal with that the second input signal delayed by the second delay circuit and outputting the compared result.

2. The phase difference detecting circuit according to claim 1, wherein each of the first, second, and third phase comparing means comprises a flip-flop circuit in which, in the case where the phase of the first input signal leads that of the second input signal, a signal of a level H is outputted from an output terminal corresponding to the first input signal and a signal of a level L is outputted from an output terminal corresponding to the second input signal, whereas in the case where the phase of the first input signal lags that of the second input signal, a signal of a level L is outputted from an output terminal corresponding to the first input signal and a signal of a level H is outputted from an output terminal corresponding to the second input signal.

3. A phase difference detecting circuit comprising:
first phase comparing means for comparing the phase of a first input signal with that of a second input signal and outputting the compared result;
a plurality of first delay circuits for delaying the first input signal by respective different period of times from each other;
a plurality of second delay circuits for delaying the second input signal by respective different period of times from each other;
a plurality of second phase comparing means for comparing the phase of the second input signal with that of the first input signals delayed respectively by the plurality of first delay circuits and outputting the compared results; and
a plurality of third phase comparing means for comparing the phase of the first input signal with that of the second input signals delayed respectively by the plurality of second delay circuits and outputting the compared results.

4. The phase difference detecting circuit according to claim 3, wherein each of the first comparing means, the plurality of second phase comparing means and the plurality of third phase comparing means comprises a flip-flop circuit in which, in the case where the phase of the first input signal leads that of the second input signal, a signal of a level H is outputted from an output terminal corresponding to the first input signal and a signal of a level L is outputted from an output terminal corresponding to the second input signal, whereas in the case where the phase of the first input signal lags that of the second input signal, a signal of a level L is outputted from an output terminal corresponding to the first input signal and a signal of a level H is outputted from an output terminal corresponding to the second input signal.

5. The phase difference detecting circuit according to claim 3, wherein each of the plurality of first delay circuits comprises a different number of delay elements connected in series, and wherein each of the plurality of second delay circuits comprises those connected in series.

6. The phase difference detecting circuit according to claim 5, wherein the number of delay elements mounted in each of the plurality of first delay circuits and those mounted in each of the plurality of second delay circuits increase at an exponential rate.

7. The phase difference detecting circuit according to claim 5, wherein the number of delay elements mounted in each of the plurality of first delay circuits and those mounted in each of the plurality of second delay circuits increase in an arithmetic progression.

8. The phase difference detecting circuit according to claim 1, wherein the phase difference detecting circuit is applied to the phase difference detecting circuit section of a PLL circuit.

9. The phase difference detecting circuit according to claim 1, wherein the phase difference detecting circuit is applied to the phase difference detecting circuit section of a DLL circuit.
